(19) United States
(12) Patent Application Publication
(10) Pub. No.: US 2020/0154566 A1
(43) Pub. Date: May 14, 2020

(54) WIRING SUBSTRATE AND ELECTRONIC DEVICE

(71) Applicant: FUJITSU LIMITED, Kawasaki-shi (JP)

(72) Inventors: Toshiki IWAI, Atsugi (JP); Taiji SAKAI, Yokohama (JP)

(73) Assignee: FUJITSU LIMITED, Kawasaki-shi (JP)

(21) Appl. No.: 16/663,421

(22) Filed: Oct. 25, 2019

(30) Foreign Application Priority Data
Nov. 8, 2018 (JP) 2018-210533

(51) Int. Cl. H05K 1/11; H05K 3/46; H01L 23/15; H01L 23/29; H01L 23/00; H05K 1/09; H05K 3/40

(52) U.S. Cl. CPC H05K 1/11; H05K 3/4623; H01L 23/15; H05K 2201/095; H01L 24/29; H05K 1/092; H05K 3/4038; H01L 23/295

(57) ABSTRACT

A wiring substrate includes: a first plate member including a first surface and a second surface opposite to the first surface; a first through wiring configured to extend in a tubular shape from the first surface to the second surface along an inner peripheral surface of a first through hole; a conductive member provided at an end of the first through wiring on a first surface side of the first plate member; a second plate member including a third surface and a fourth surface opposite to the third surface, the fourth surface facing the first surface of the first plate member; and a second through wiring configured to extend from the third surface to the fourth surface along an inner peripheral surface of a second through hole and be in contact with the conductive member.

### CROSS-REFERENCE TO RELATED APPLICATION

This application is based upon and claims the benefit of priority of the prior Japanese Patent Application No. 2018-210533 filed on Nov. 8, 2018, the entire contents of which are incorporated herein by reference.

### FIELD

A certain aspect of the embodiments is related to a wiring substrate and an electronic device.

### BACKGROUND

There has been known a structure for achieving electrical conduction between a wiring formed on a first surface of a substrate and a wiring formed on a second surface thereof by using a through conductor formed by filling a conductive paste in a through hole penetrating between the first surface and the second surface of the substrate. For example, it is known that, when the diameter of the through hole on the first surface of the substrate is made larger than that of the through hole on the second surface, and the diameter of a local minimum value is formed between the first surface and the second surface, the filling of the conductive paste in the through hole can be improved and the dropout of the through conductor can be suppressed (e.g. see Patent Document 1: Japanese Laid-open Patent Publication No. 2015-146410).

### SUMMARY

According to a first aspect of the present invention, there is provided a wiring substrate including: a first plate member including a first surface and a second surface opposite to the first surface; a first through wiring configured to extend in a tubular shape from the first surface to the second surface along an inner peripheral surface of a first through hole, the first through hole penetrating the first plate member from the first surface to the second surface and including a shape in which a width of the first through hole increases from an intermediate portion between the first surface and the second surface toward the first surface; a conductive member provided at an end of the first through wiring on a first surface side of the first plate member; a second plate member including a third surface and a fourth surface opposite to the third surface, the fourth surface facing the first surface of the first plate member; and a second through wiring configured to extend from the third surface to the fourth surface along an inner peripheral surface of a second through hole and be in contact with the conductive member, the second through hole penetrating the second plate member from the third surface to the fourth surface.

According to a second aspect of the present invention, there is provided an electronic device including: a wiring substrate; and an electronic component mounted on the wiring substrate; the wiring substrate including: a first plate member including a first surface and a second surface opposite to the first surface; a first through wiring configured to extend in a tubular shape from the first surface to the second surface along an inner peripheral surface of a first through hole, the first through hole penetrating the first plate member from the first surface to the second surface and including a shape in which a width of the first through hole increases from an intermediate portion between the first surface and the second surface toward the first surface; a conductive member provided at an end of the first through wiring on a first surface side of the first plate member; a second plate member including a third surface and a fourth surface opposite to the third surface, the fourth surface facing the first surface of the first plate member; and a second through wiring configured to extend from the third surface to the fourth surface along an inner peripheral surface of a second through hole and be in contact with the conductive member, the second through hole penetrating the second plate member from the third surface to the fourth surface.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a cross-sectional view of a wiring substrate according to a first embodiment;

FIG. 2A is a plan view of a through hole as viewed from an upper surface side of a plate member;

FIG. 2B is a plan view of the through hole as viewed from a lower surface side of the plate member;

FIG. 3A is a plan view of a conductive member as viewed from the upper surface side of the plate member;

FIG. 3B is a cross-sectional perspective view of the plate member near a through hole;

FIGS. 4A to 4E are cross-sectional views illustrating a method of manufacturing a wiring substrate according to the first embodiment (part 1);

FIGS. 5A and 5B are cross-sectional views illustrating the method of manufacturing the wiring substrate according to the first embodiment (part 2);

FIGS. 6A and 6B are cross-sectional views illustrating the method of manufacturing the wiring substrate according to the first embodiment (part 3);

FIG. 7 is a cross-sectional view of the wiring substrate according to a comparative example;

FIGS. 8A and 8B are diagrams illustrating the structure of the wiring substrates according to the first embodiment and the comparative example in which simulation has been performed;

FIGS. 8C and 8D are diagrams illustrating simulation results of the wiring substrates according to the first embodiment and the comparative example;

FIG. 9 is a cross-sectional view of the wiring substrate according to a second embodiment;

FIG. 10 is a cross-sectional view of the wiring substrate according to a third embodiment;

FIGS. 11A to 11D are cross-sectional views illustrating the method of manufacturing the wiring substrate according to the third embodiment (part 1);

FIGS. 12A to 12C are cross-sectional views illustrating the method of manufacturing the wiring substrate according to the third embodiment (part 2);

FIGS. 13A and 13B are cross-sectional views illustrating the method of manufacturing the wiring substrate according to the third embodiment (part 3);

FIG. 14A is a diagram illustrating the structure of the wiring substrate according to the third embodiment in which the simulation has been performed;

FIG. 14B is a diagram illustrating a simulation result of the wiring substrate according to the third embodiment;

FIGS. 15A and 15B are cross-sectional views illustrating other examples of the through hole;

FIGS. 16A and 16B are plan views illustrating other examples of the conductive member; and

FIG. 17 is a cross-sectional view of an electronic device according to a fourth embodiment.

### DESCRIPTION OF EMBODIMENTS

In the Patent Document 1, it is considered to get electrical conduction between a plurality of plate members by using a through wiring extending along an inner peripheral surface of a through hole penetrating between a first surface and a second surface of the plate member, and a conductive member made of the conductive paste filled inside the through wiring. However, in this case, a stress resulting from thermal expansion of the through wiring or the like may be applied to the plate member, and cracks may occur in the plate member.

A wiring substrate and an electronic device according to the present embodiments can suppress the occurrence of cracks.

A description will now be given of an embodiment of the present invention with reference to the drawings.

### First Embodiment

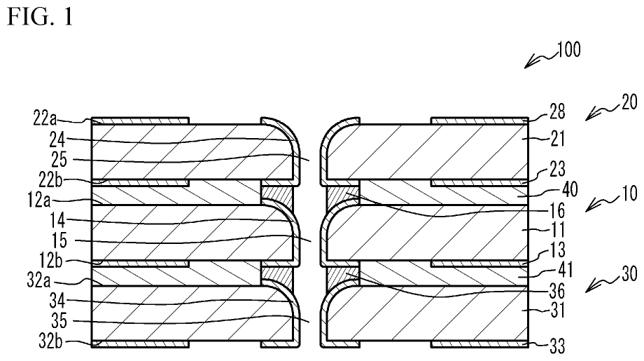

FIG. 1 is a cross-sectional view of a wiring substrate according to a first embodiment. As illustrated in FIG. 1, a wiring substrate 100 according to the first embodiment is a multilayer wiring substrate in which a plurality of single-layer plates 10, 20, and 30 are stacked. In the following, for convenience of explanation, an upper and lower relationship in FIG. 1 is used to refer to an upper or a lower direction.

The single-layer plate 10 includes a plate member 11, a wiring layer 13, a through wiring 14, and a conductive member 16. The plate member 11 is made of, for example, a brittle material, but may be made of another material. The plate member 11 may be, for example, an insulating substrate made of glass, sapphire or the like which is the brittle material, or may be a semiconductor substrate made of silicon, gallium nitride or the like which is the brittle material. The thickness of the plate member 11 is, for example, about 10 μm to 1000 μm, and is 100 μm as an example.

The wiring layer 13 is provided on a lower surface 12b of the plate member 11. The wiring layer 13 is a metal wiring layer including, for example, at least one of copper (Cu), gold (Au), nickel (Ni), aluminum (Al), and palladium (Pd). The thickness of the wiring layer 13 is, for example, about 0.1 μm to 40 μm, and is 5 μm as an example.

The through wiring 14 is provided to extend along an inner peripheral surface of a through hole 15 which penetrates the plate member 11. The through hole 15 penetrates from an upper surface 12a of the plate member 11 to the lower surface 12b thereof. The through wiring 14 is electrically connected to the wiring layer 13. The through wiring 14 is a metal layer containing, for example, at least one of copper (Cu), gold (Au), nickel (Ni), and palladium (Pd). The through wiring 14 is made of, for example, the same material as the wiring layer 13, but may be made of a different material.

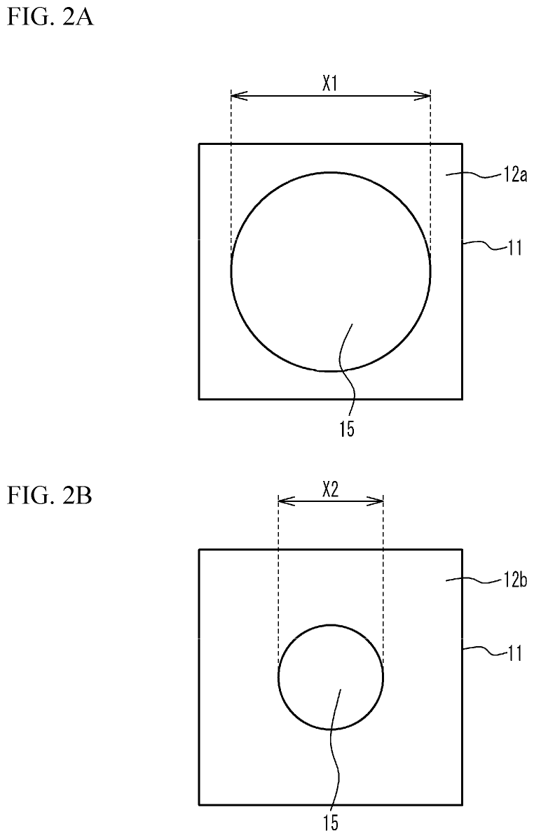

Here, the through hole 15 will be described by using FIGS. 2A and 2B together with FIG. 1. FIG. 2A is a plan view of the through hole 15 as viewed from an upper surface side of the plate member 11. FIG. 2B is a plan view of the through hole 15 as viewed from a lower surface side of the plate member 11. As illustrated in FIGS. 1, 2A and 2B, a width (i.e., diameter) of the through hole 15 on the upper surface 12a of the plate member 11 is made larger than a width (diameter) thereof on the lower surface 12b. A width (diameter) X1 of the through hole 15 on the upper surface 12a of the plate member 11 is, for example, about 20 μm to about 1000 μm, and is 200 μm as an example. An aspect ratio (i.e., a ratio of the width (diameter) X1 to the thickness of the plate member 11) is, for example, about 0.1 to 10. A width (diameter) X2 of the through hole 15 on the lower surface 12b of the plate member 11 is, for example, about 10 μm to about 500 μm, and is 100 μm as an example.

The through hole 15 has a cylindrical shape maintaining the width (diameter) of the through hole 15 on the lower surface 12b from the lower surface 12b of the plate member 11 to an intermediate portion between the upper surface 12a and the lower surface 12b, for example. The through hole 15 has a shape in which the width (diameter) gradually widens from the intermediate portion between the upper surface 12a and the lower surface 12b of the plate member 11 to the upper surface 12a, for example. The through hole 15 has a shape in which the inner peripheral surface of the through hole 15 is inclined in an arc shape from the intermediate portion between the upper surface 12a and the lower surface 12b toward the upper surface 12a, for example. Such a shape of the through hole 15 is referred to as a trumpet shape.

As illustrated in FIG. 1, the through wiring 14 extends along the inner peripheral surface of the through hole 15 from the upper surface 12a to the lower surface 12b, and parts of the through wiring 14 are provided on the upper surface 12a and the lower surface 12b. The through wiring 14 is provided, for example, on the entire inner peripheral surface of the through hole 15, and has a tubular shape. The thickness of the through wiring 14 on the inner peripheral surface of the through hole 15 is, for example, about 0.1 μm to 40 μm, and is 5 μm as an example. An inner part of the through wiring 14 is hollow.

The conductive member 16 is provided at an end of the through wiring 14 on an upper surface 12a side of the plate member 11. The conductive member 16 is in contact with the through wiring 14. The conductive member 16 protrudes upwards from the upper surface 12a of the plate member 11. The conductive member 16 is formed by melting a conductive paste containing metal particles and a resin. Therefore, the conductive member 16 is made of a resin containing a metal. The metal includes, for example, an intermetallic compound (IMC) containing at least one of copper (Cu), tin (Sn), silver (Ag), bismuth (Bi), indium (In), antimony (Sb), lead Pb), aluminum (Al), and zinc (Zn). The resin includes a thermosetting resin such as an epoxy resin, or a thermoplastic resin such as an acrylic resin or a polyimide resin, for example.

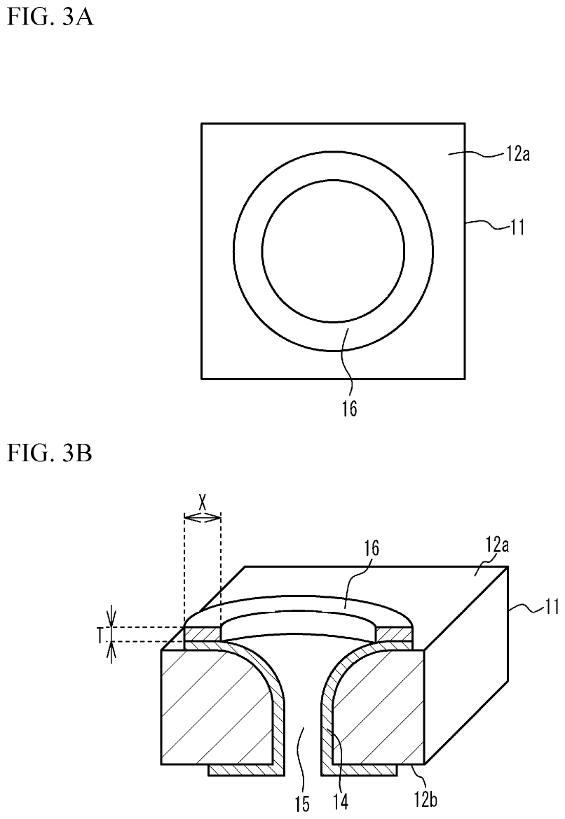

Here, the conductive member 16 will be described with reference to FIGS. 3A and 3B. FIG. 3A is a plan view of the conductive member 16 as viewed from the upper surface side of the plate member 11. FIG. 3B is a cross-sectional perspective view of the plate member 11 near the through hole 15. As illustrated in FIGS. 3A and 3B, the conductive member 16 is annularly provided on the through wiring 14 along the end of the through wiring 14 on the upper surface 12 side of the plate member 11. A width X of the conductive member 16 is, for example, about 1 μm to 50 μm, and is 10 μm as an example. A thickness T of the conductive member 16 is, for example, about 1 μm to 100 μm, and is 30 μm as an example.

As illustrated in FIG. 1, the single-layer plate 20 includes a plate member 21, a wiring layer 23, a through wiring 24, and a wiring layer 28. The plate member 21 is a substrate made of, for example, the brittle material, and is an insulating substrate made of glass, sapphire or the like, or a semiconductor substrate made of silicon, gallium nitride or the like. But, the plate member 21 may be a substrate made of other material. The thickness of the plate member 21 is, for example, about 10 μm to 1000 μm, and is 100 μm as an example.

The wiring layer 23 is provided on a lower surface 22b of the plate member 21. The wiring layer 28 is provided on an upper surface 22a of the plate member 21. The wiring layers 23 and 28 are metal wiring layers including, for example, at least one of copper (Cu), gold (Au), nickel (Ni), aluminum (Al), and palladium (Pa). Each thickness of the wiring layers 23 and 28 is, for example, about 0.1 μm to 40 μm, and is 5 μm as an example.

The through wiring 24 is provided to extend along an inner peripheral surface of a through hole 25 which penetrates the plate member 21. The through hole 25 penetrates from the upper surface 22a to the lower surface 22b of the plate member 21. The through hole 25 has the same trumpet shape as the through hole 15 penetrating the single-layer plate 10 described in FIGS. 1, 2A, and 2B. The through wiring 24 is electrically connected to the wiring layers 23 and 28. The through wiring 24 extends along the inner peripheral surface of the through hole 25 from the upper surface 22a to the lower surface 22b, and parts of the through wiring 24 are provided on the upper surface 22a and the lower surface 22b. The through wiring 24 is provided, for example, on the entire inner peripheral surface of the through hole 25 and has a tubular shape. The through wiring 24 is a metal layer including, for example, at least one of copper (Cu), gold (Au), nickel (Ni), and palladium (Pd). The through wiring 24 is made of, for example, the same material as the wiring layers 23 and 28, but may be made of a different material from the wiring layers 23 and 28. The thickness of the through wiring 24 on the inner peripheral surface of the through hole 25 is, for example, about 0.1 μm to 40 μm, and is 5 μm as an example. An inner part of the through wiring 24 is hollow.

The single-layer plate 30 includes a plate member 31, a wiring layer 33, a through wiring 34, and a conductive member 36. The plate member 31 is a substrate made of, for example, the brittle material, and is an insulating substrate made of glass, sapphire or the like, or a semiconductor substrate made of silicon, gallium nitride or the like. But, the plate member 31 may be a substrate made of other material. The thickness of the plate member 31 is, for example, about 10 μm to 1000 μm, and is 100 μm as an example.

The wiring layer 33 is provided on a lower surface 32b of the plate member 31. The wiring layer 33 is a metal wiring layer including, for example, at least one of copper (Cu), gold (Au), nickel (Ni), aluminum (Al), and palladium (Pd). The thickness of the wiring layer 33 is, for example, about 0.1 μm to 40 μm, and is 5 μm as an example.

The through wiring 34 is provided to extend along an inner peripheral surface of a through hole 35 which penetrates the plate member 31. The through hole 35 penetrates from an upper surface 32a to the lower surface 32b of the plate member 31. The through hole 35 has the same trumpet shape as the through hole 15 penetrating the single-layer plate 10 described in FIGS. 1, 2A, and 2B. The through wiring 34 is electrically connected to the wiring layer 33. The through wiring 34 extends along the inner peripheral surface of the through hole 35 from the upper surface 32a to the lower surface 32b, and parts of the through wiring 34 are provided on the upper surface 32a and the lower surface 32b. The through wiring 34 is provided, for example, on the entire inner peripheral surface of the through hole 35 and has a tubular shape. The through wiring 34 is a metal layer including, for example, at least one of copper (Cu), gold (Au), nickel (Ni), and palladium (Pa). The through wiring 34 is made of, for example, the same material as the wiring layer 33, but may be made of a different material from the wiring layer 33. The thickness of the through wiring 34 on the inner peripheral surface of the through hole 35 is, for example, about 0.1 μm to 40 μm, and is 5 μm as an example. An inner part of the through wiring 34 is hollow.

The conductive member 36 is provided in contact with an end of the through wiring 34 on an upper surface 32 side of the plate member 31, and protrudes upwards from the upper surface 32a of the plate member 31. The conductive member 36 has the same annular shape as the conductive member 16 of the single-layer plate 10 described in FIGS. 3A and 3B. The conductive member 36 is formed by melting a conductive paste containing metal particles and a resin. Therefore, the conductive member 36 is made of a resin containing a metal. The metal includes, for example, an IMC containing at least one of copper (Cu), tin (Sn), silver (Ag), bismuth (Bi), indium (In), antimony (Sb), lead (Pb), aluminum (Al), and zinc (Zn). The resin includes a thermosetting resin such as an epoxy resin, or a thermoplastic resin such as an acrylic resin or a polyimide resin, for example.

In the wiring substrate 100, the upper surface 12a of the plate member 11 and the lower surface 22b of the plate member 21 are opposite to each other, the lower surface 12b of the plate member 11 and the upper surface 32a of the plate member 31 are opposite to each other, and the single-layer plates 10, 20 and 30 are stacked. The plate members 11 and 21 are adhered by a resin layer 40 provided therebetween. The conductive member 16 provided on the through wiring 14 is in contact with the through wiring 24 at the lower surface 22b of the plate member 21. Thereby, the through wirings 14 and 24 are electrically connected to each other via the conductive member 16. Similarly, the plate members 11 and 31 are adhered by a resin layer 41 provided therebetween. The conductive member 36 provided on the through wiring 34 is in contact with the through wiring 14 at the lower surface 12b of the plate member 11. Thereby, the through wirings 14 and 34 are electrically connected to each other via the conductive member 36. The resin layers 40 and 41 may be made of the thermosetting resin, or may be made of the thermoplastic resin. Also, the thermosetting resin and the thermoplastic resin may contain a filler such as glass.

In the first embodiment, each of the plate members 11, 21 and 31 is assumed to be a glass substrate. Non-alkali glass, quartz glass, borosilicate glass or the like can be used as the glass substrate. Each of the wiring layers 13, 23, 28, and 33 is assumed to be a Cu wiring layer. Each of the through wirings 14, 24, and 34 is assumed to be a Cu through wiring. Each of the conductive members 16 and 36 is assumed to be made of an epoxy resin containing a SnCu IMC. Each of the resin layers 40 and 41 is assumed to be made of an epoxy resin which is the thermosetting resin.

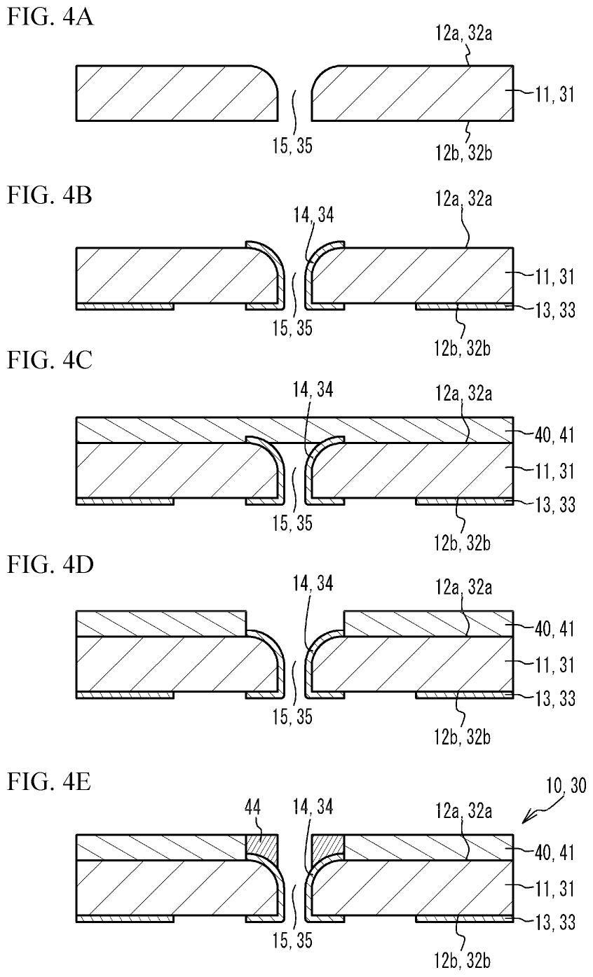

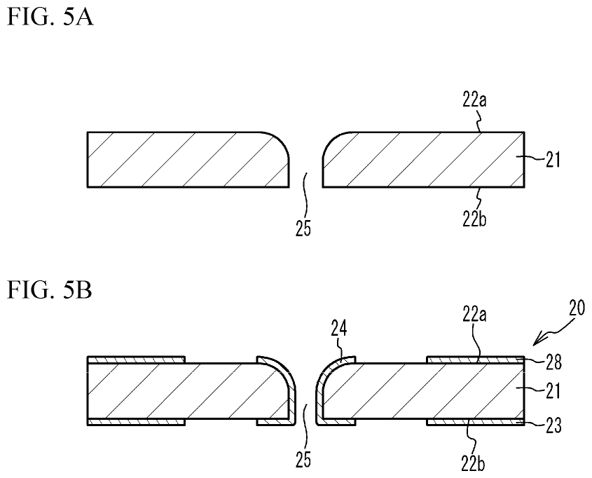

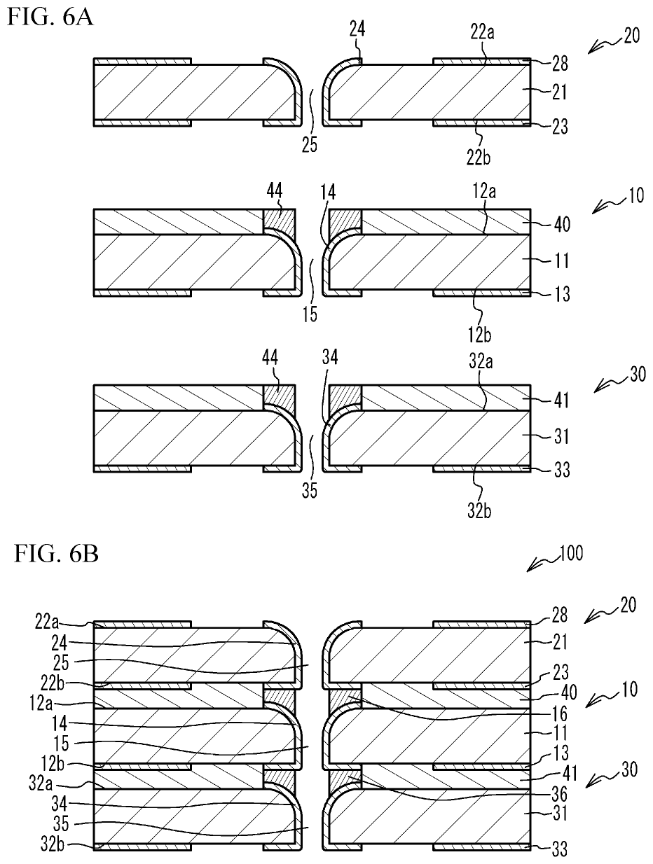

FIGS. 4A to 6B are cross-sectional views illustrating a method of manufacturing the wiring substrate according to the first embodiment. FIGS. 4A to 4E are cross-sectional views illustrating a method of manufacturing the single-layer plates 10 and 30. FIGS. 5A and 5B are cross-sectional views illustrating a method of manufacturing the single-layer plate 20. FIGS. 6A and 6B are cross-sectional views illustrating a step of stacking the single-layer plates 10, 20 and 30.

As illustrated in FIG. 4A, the through holes 15 and 35 are formed in the plate members 11 and 31 which are glass substrates by using laser processing and wet etching. For example, by adjusting the power of the laser beam irradiated to the plate members 11 and 31, the through holes are formed to have a constant width from the lower surfaces 12b and 32b of the plate members 11 and 31 to the intermediate portions between the lower surfaces 12b and 32b and the upper surfaces 12a and 32a, and spread stepwise from the intermediate portions to the upper surfaces 12a and 32a. Then, the plate members 11 and 31 are immersed in hydrofluoric acid, and the trumpet-shaped through holes 15 and 35 in which the inner peripheral surfaces are inclined in the arc shape from the intermediate portions toward the upper surfaces 12a and 32a are formed. A carbon dioxide gas laser, an ultraviolet laser, an excimer laser, or the like can be used for the laser processing. The through holes 15 and 35 may be formed, for example, only by laser processing, may be formed by mechanical drilling such as a drill, or may be formed by sandblasting.

As illustrated in FIG. 4B, after forming copper (Cu) seed layers on the plate members 11 and 31 using electroless plating, copper (Cu) plating layers are formed by electrolytic plating using plating resist films as masks. Thereby, the wiring layers 13 and 33 which are Cu wiring layers and the through wirings 14 and 34 which are Cu through wirings are formed on the plate members 11 and 31, respectively.

As illustrated in FIG. 4C, the resin layers 40 and 41 made of the epoxy resin are formed on the upper surfaces 12a and 32a of the plate members 11 and 31 by a laminating method. By adjusting the temperature at the time of lamination, the epoxy resin is not embedded in the through holes 15 and 35, and the resin layers 40 and 41 are formed on the upper surfaces 12a and 32a of the plate members 11 and 31, respectively.

As illustrated in FIG. 4D, the resin layers 40 and 41 formed on the through holes 15 and 35 and the through wirings 14 and 34 are removed by a laser or the like so as to expose the through wirings 14 and 34.

As illustrated in FIG. 4E, a conductive paste 44 is applied to the ends of the through wirings 14 and 34 from the upper surface 12a and 32a sides of the plate members 11 and 31 by a dispensing method or an ink jet method. Thereby, the single-layer plates 10 and 30 are formed.

As illustrated in FIG. 5A, the through hole 25 is formed in the plate member 21 which is the glass substrate using the laser processing and the wet etching processing. The through hole 25 can be formed using the same method as the through holes 15 and 35 described in FIG. 4A.

As illustrated in FIG. 5B, the wiring layers 23 and 28 which are Cu wiring layers and the through wiring 24 which is the Cu through wiring are formed on the plate member 21. The wiring layers 23 and 28 and the through wiring 24 can be formed using the same method as the wiring layers 13 and 33 and the through wirings 14 and 34 described in FIG. 4B. Thereby, the single-layer plate 20 is formed.

As illustrated in FIG. 6A, the single-layer plates 10 and 30 formed according to FIGS. 4A to 4E and the single-layer plate 20 formed according to FIGS. 5A and 5B are stacked.

As illustrated in FIG. 6B, heat pressing, for example, at 200° C., 3 MPa, for 90 minutes is performed to the stacked single-layer plates 10, 20 and 30 by using a vacuum heat press machine. The conductive member 16 made of the conductive paste 44 formed on the plate member 11 is bonded to the through wirings 14 and 24 by the heat pressing. The conductive member 36 made of the conductive paste 44 formed on the plate member 31 is bonded to the through wirings 34 and 14. The resin layers 40 and 41 are cured by heating, so that the single-layer plates 10, 20 and 30 are bonded and held. Thereby, the wiring substrate 100 is formed.

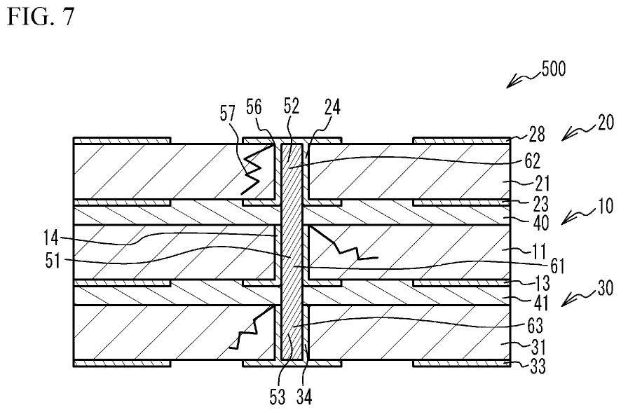

Next, a description will be given of the wiring substrate of a comparative example. FIG. 7 is a cross-sectional view of the wiring substrate according to the comparative example. As illustrated in FIG. 7, in a wiring substrate 500 of the comparative example, the through holes 51, 52, and 53 penetrating the plate members 11, 21, and 31 have cylindrical shapes, not the trumpet shapes. The conductive members 16 and 36 are not provided on the through wirings 14 and 34 provided on the inner peripheral surfaces of the through holes 51 and 53. As substitute for the conductive members 16 and 36, conductive members 61, 62 and 63 made of the same material as the conductive members 16 and 36 are embedded in the through holes 51, 52 and 53, respectively. Since the conductive members 61, 62, and 63 are in contact with each other, the single-layer plates 10, 20, and 30 are electrically conducted. Since other configurations are the same as those in the first embodiment, a description thereof is omitted. The through wirings 14, 24 and 34 are provided to reduce resistances between the single-layer plates 10, 20 and 30. Also, as is the case with the wiring substrate 100 of the first embodiment, the wiring substrate 500 of the comparative example is formed by performing the heat pressing on the stacked single-layer plates 10, 20, and 30 using the vacuum heat press machine.

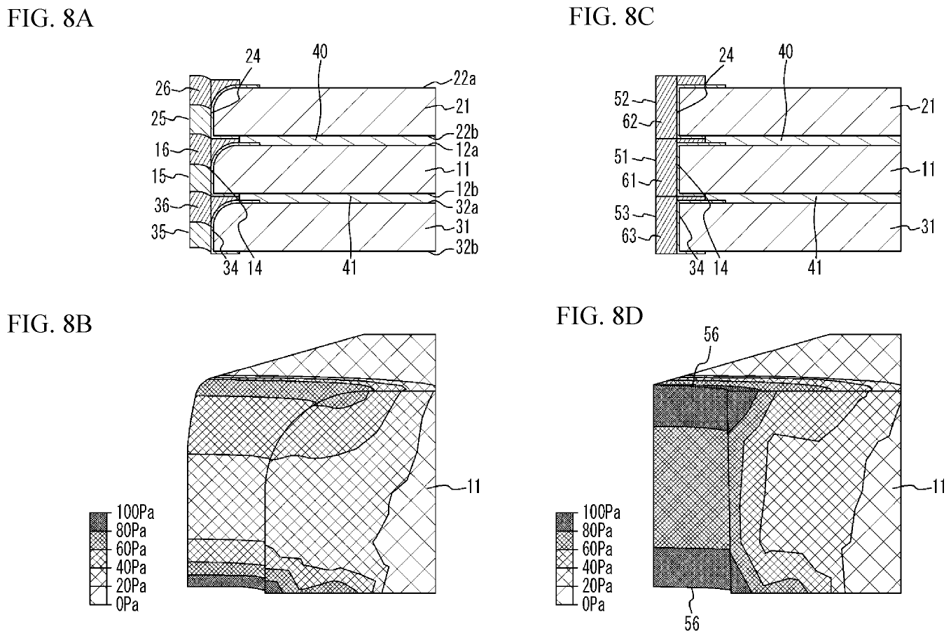

Here, a description will be given of simulation performed on the wiring substrate 100 of the first embodiment and the wiring substrate 500 of the comparative example. FIGS. 8A and 8B are diagrams illustrating the structure of the wiring substrates according to the first embodiment and the comparative example in which the simulation has been performed. As illustrated in FIG. 8A, in the wiring substrate of the first embodiment in which the simulation has been performed, each of the plate members 11, 21 and 31 is a glass substrate having a thickness of 100 μm. Each of the through holes 15, 25, and 35 on the lower surface 12b, 22b, and 32b side of the plate members 11, 21, and 31 has a diameter of 100 μm, and each of the through holes 15, 25, 25 on the upper surface 12a, 22a, and 32a side of the plate members 11, 21, and 31 has a diameter of 200 μm. Each of the through wirings 14, 24, and 34 is a copper (Cu) through wiring having a thickness of 5 μm. The conductive members 16 and 36 are made of an epoxy resin containing a SnCu IMC. A conductive member 26 made of the epoxy resin containing the SnCu IMC is also provided on the through wiring 24 provided on the plate member 21. As illustrated in FIG. 8B, in the wiring substrate of the comparative example in which the simulation has been performed, each of the through holes 51, 52, and 53 is formed in the cylindrical shape with a diameter of 100 μm. The conductive members 61, 62, and 63 embedded in the through holes 51, 52, and 53 are made of the epoxy resin containing the SnCu IMC. Other configurations are the same as those of FIG. 8A.

FIGS. 8C and 8D are diagrams illustrating simulation results of the wiring substrates according to the first embodiment and the comparative example. In the simulation, the stress generated in the plate member 11 is calculated on the condition that the stacked structure illustrated in FIGS. 8A and 8B is heat pressed in the stacking direction at 200° C. and 30 kg/cm². As illustrated in FIGS. 8C and 8D, in the first embodiment, the stress generated in the plate member 11 is reduced as compared with the comparative example. As described above, it is considered that, in the wiring substrate of the comparative example, the stress generated in the plate member 11 is large due to the following reason. That is, the thermal expansion coefficients of glass which is the material of the plate member 11 and copper (Cu) which is the material of the through wiring 14 are different from each other (for example, a linear expansion coefficient of glass is 3×10⁻⁶/° C., and the linear expansion coefficient of copper is 16.8×10⁻⁶/° C.). For this reason, the plate member 11 and the through wiring 14 are thermally expanded according to the respective thermal expansion coefficients with respect to rise in temperature. At this time, when the conductive member 61 is filled in the through hole 51, the through wiring 14 is hard to thermally expand in an inner direction of the through hole 51. For this reason, it is considered that the stress is easily applied to the plate member 11 due to the thermal expansion of the through wiring 14. Further, it is considered that the stress is applied to the plate member 11 also by the heat pressing. Since such a stress tends to concentrate on a corner portion 56 of the plate member 11, it is considered that a large stress is generated in the corner portion 56. Similarly, it is considered that the large stress is also generated in the corner portions 56 of the plate members 21 and 31. Thus, the large stress is generated in the corner portions 56 of the plate members 11, 21, and 31, so that cracks 57 may be generated in the plate members 11, 21, and 31 from the corner portions 56 as illustrated in FIG. 7.

On the contrary, it is considered that, in the wiring substrate of the first embodiment, the stress generated in the plate member 11 is small due to the following reason. That is, the through hole 15 penetrating the plate member 11 has the trumpet shape in which the width (i.e., the diameter) of the through hole 15 increases from the intermediate portion between the upper surface 12a and the lower surface 12b of the plate member 11 toward the upper surface 12a. The through wiring 14 extends along the inner peripheral surface of the trumpet-shaped through hole 15 and has the tubular shape. The conductive member 16 is provided at the end of the through wiring 14 on the upper surface 12 side of the plate member 11. The inner part of the through wiring 14 is hollow. As described above, since the inner part of the through wiring 14 is hollow, it is considered that the through wiring 14 is easily thermally expanded in the inner direction of the through hole 15, and the stress applied to the plate member 11 is reduced. Since the through hole 15 has the trumpet shape in which the width of the through hole 15 increases from the intermediate portion between the upper surface 12a and the lower surface 12b of the plate member 11 toward the upper surface 12a, it is considered that a portion where the stress tends to concentrate on the plate member 11 is hardly generated. For this reason, it is considered that the stress generated in the plate member 11 is small in the wiring substrate of the first embodiment. Similarly, it is considered that the stress generated in the plate members 21 and 31 is also small.

According to the first embodiment, as illustrated in FIG. 1, the tubular through wiring 14 extends along the inner peripheral surface of the through hole 15 penetrating the plate member 11 from the upper surface 12a to the lower surface 12b and having the shape in which the width of the through hole 15 increases from the intermediate portion between the upper surface 12a and the lower surface 12b toward the upper surface 12a. The conductive member 16 is provided at the end of the through wiring 14 on the upper surface 12a side of the plate member 11. The conductive member 16 is in contact with the through wiring 24 extending along the inner peripheral surface of the through hole 25 that penetrates the plate member 21 opposite to the plate member 11 from the upper surface 22a to the lower surface 22b. Thereby, when the temperature rises at the time of manufacture and use, the through wiring 14 is easily thermally expanded toward the inner side of the through hole 15, and the portion where the stress tends to concentrate is hard to be generated in the plate member 11. Therefore, the stress to be generated in the plate member 11 can be reduced, and the occurrence of the cracks in the plate member 11 can be suppressed. Further, since the through wiring 14 and the through wiring 24 are connected by the conductive member 16, connection reliability between the through wiring 14 and the through wiring 24 can be improved.

As illustrated in FIG. 1, the inner part of the through wiring 14 is preferably hollow. Thereby, since the through wiring 14 is easily thermally expanded in the inner direction of the through hole 15, the stress to be generated in the plate member 11 can be reduced, and the occurrence of the cracks in the plate member 11 can be effectively suppressed.

As illustrated in FIGS. 1 and 3B, a portion of the inner peripheral surface of the through hole 15 where the width of the through hole 15 increases from the intermediate portion between the upper surface 12a and the lower surface 12b of the plate member 11 toward the upper surface 12a is preferably inclined in the arc shape. Thereby, the portion (i.e., the corner portion) where the stress tends to concentrate is hard to be generated in the plate member 11, and the stress to be generated in the plate member 11 can be reduced.

As illustrated in FIGS. 3A and 3B, the conductive member 16 is preferably provided annularly on the through wiring 14. Thereby, contact areas between the conductive member 16 and the through wirings 14 and 24 can be increased, and the connection reliability of the conductive member 16 between the through wirings 14 and 24 can be improved.

When the plate member 11 is made of the brittle material, the plate member 11 is easily cracked by the stress. Therefore, when the plate member 11 is made of the brittle material, the through hole 15 preferably has the shape in which the width increases from the intermediate portion between the upper surface 12a and the lower surface 12b of the plate member 11 toward the upper surface 12a. Moreover, the conductive member 16 is preferably formed at the end of the through wiring 14 on the upper surface 12 side of the plate member 11.

The conductive member 16 is preferably made of the resin containing the metal. Thereby, the connection reliability of the through wiring 14 and the through wiring 24 through the conductive member 16 can be improved.

### Second Embodiment

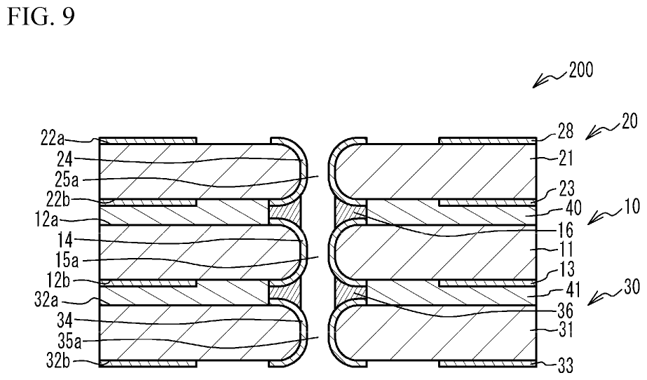

FIG. 9 is a cross-sectional view of the wiring substrate according to a second embodiment. As illustrated in FIG. 9, in a wiring substrate 200 of the second embodiment, the width of a through hole 15a penetrating the plate member 11 increases from the intermediate portion between the upper surface 12a and the lower surface 12b of the plate member 11 toward both of the upper surface 12a and the lower surface 12b. The through hole 15a has a shape in which the inner peripheral surface of the through hole 15a is inclined in the arc shape from the intermediate portion between the upper surface 12a and the lower surface 12b of the plate member 11 toward the upper surface 12a and the lower surface 12b, for example. A through hole 25a penetrating the plate member 21 and a through hole 35a penetrating the plate member 31 also have the same shape as the through hole 15a. Since other configurations are the same as those in the first embodiment, a description thereof is omitted.

In the first embodiment, the through hole 15 penetrating the plate member 11 has the shape in which the width of the through hole 15 increases from the intermediate portion between the upper surface 12a and the lower surface 12b of the plate member 11 toward the upper surface 12a. For this reason, as illustrated in FIG. 8C, the stress on the upper surface 12a side of the plate member 11 can be reduced. In the second embodiment, the through hole 15a penetrating the plate member 11 has the shape in which the width of the through hole 15 increases from the intermediate portion between the upper surface 12a and the lower surface 12b of the plate member 11 toward the upper surface 12a and the lower surface 12b. Thereby, the stress can be reduced on both of the upper surface 12a side and the lower surface 12b side of the plate member 11.

### Third Embodiment

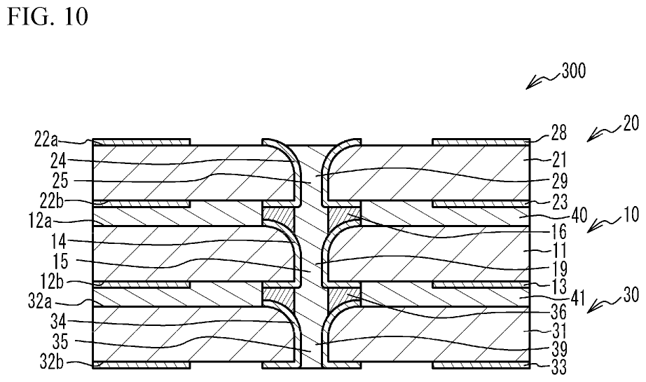

FIG. 10 is a cross-sectional view of the wiring substrate according to a third embodiment. As illustrated in FIG. 10, in a wiring substrate 300 according to the third embodiment, a resin film 19 is embedded in the inner part of the through wiring 14 provided on the inner peripheral surface of the through hole 15 that penetrates the plate member 11. Similarly, a resin film 29 is embedded in the inner part of the through wiring 24 provided on the inner peripheral surface of the through hole 25 that penetrates the plate member 21, and a resin film 39 is embedded in the inner part of the through wiring 34 provided on the inner peripheral surface of the through hole 35 that penetrates the plate member 31. The resin films 19, 29 and 39 are made of a material having a smaller elastic modulus than the conductive members 16 and 36. The resin films 19, 29 and 39 may be made of the thermosetting resin, or may be made of the thermoplastic resin. Also, the thermosetting resin and the thermoplastic resin may contain the filler such as glass. In the third embodiment, the resin films 19, 29, and 39 are made of, for example, the epoxy resin that is the thermosetting resin like the resin layers 40 and 41. Since other configurations are the same as those in the first embodiment, a description thereof is omitted.

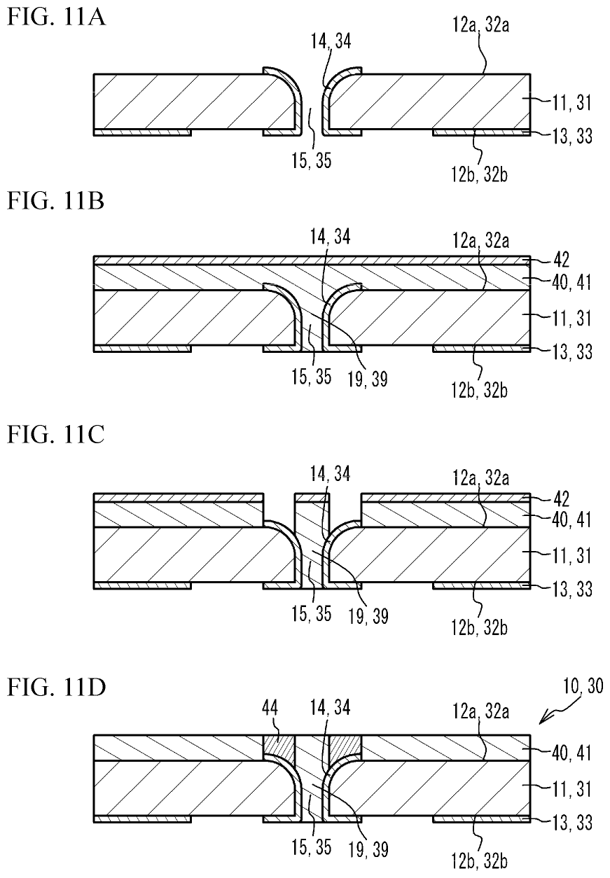

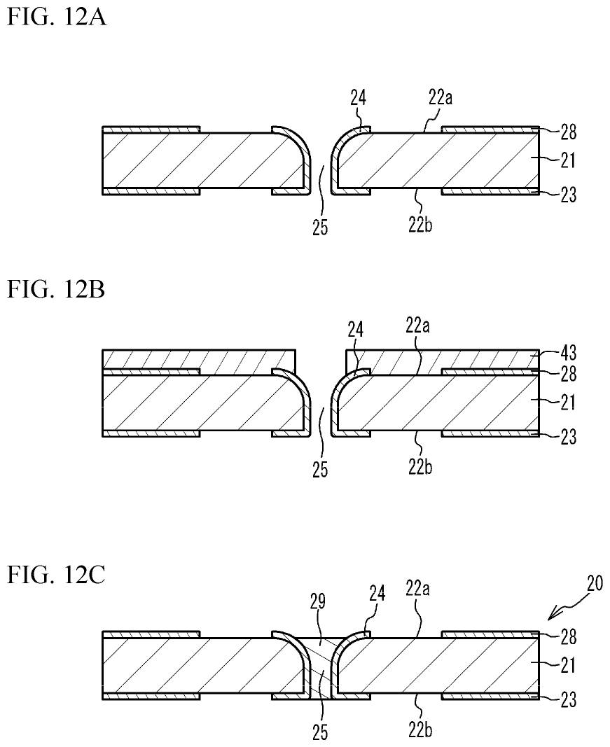

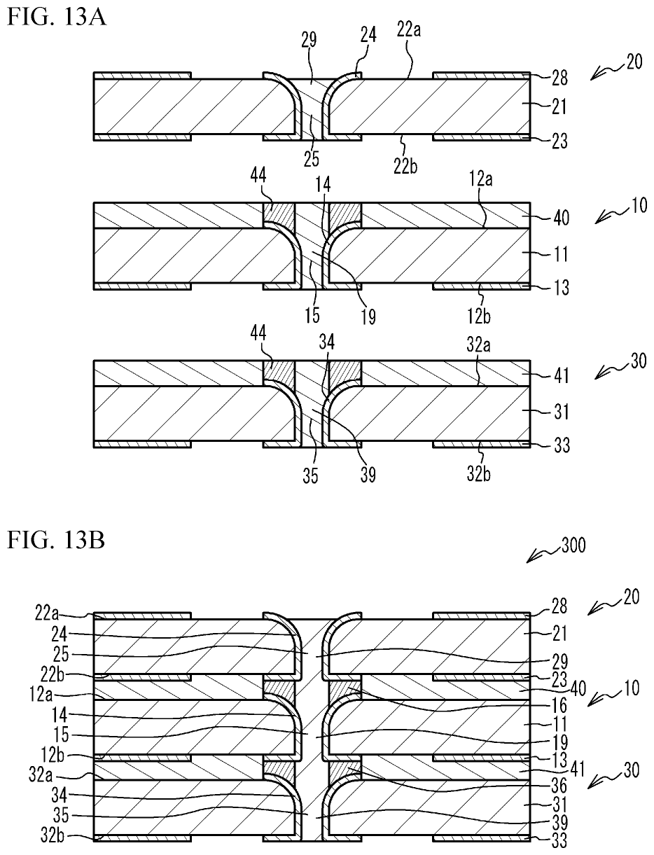

FIGS. 11A to 13B are cross-sectional views illustrating the method of manufacturing the wiring substrate according to the third embodiment. FIGS. 11A to 11D are cross-sectional views illustrating the method of manufacturing the single-layer plates 10 and 30. FIGS. 12A to 12C are cross-sectional views illustrating the method of manufacturing the single-layer plate 20. FIGS. 13A and 13B are cross-sectional views illustrating a step of stacking the single-layer plates 10, 20 and 30.

As illustrated in FIG. 11A, the through holes 15 and 35 are formed in the plate members 11 and 31. The through holes 15 and 35 can be formed by the method described in FIG. 4A of the first embodiment. Thereafter, the wiring layers 13 and 33 and the through wirings 14 and 34 are formed on the plate members 11 and 31. The wiring layers 13 and 33 and the through wirings 14 and 34 can be formed by the method described in FIG. 4B of the first embodiment.

As illustrated in FIG. 11B, the epoxy resin is applied to the upper surfaces 12a and 32a of the plate members 11 and 31 by the laminating method. Thereby, the resin layer 40 is formed on the upper surface 12a of the plate member 11, and the resin layer 41 is formed on the upper surface 32a of the plate member 31. Further, the resin film 19 is embedded in the through hole 15 penetrating the plate member 11, and the resin film 39 is embedded in the through hole 35 penetrating the plate member 31. Thereafter, a mask layer 42 made of polyethylene terephthalate is formed on the resin layers 40 and 41 by the laminating method.

As illustrated in FIG. 11C, the mask layer 42 and the resin layers 40 and 41 in regions where the conductive members 16 and 36 are to be formed are removed by laser or the like to expose the through wirings 14 and 34.

As illustrated in FIG. 11D, by screen printing using the mask layer 42 as a mask, the conductive paste 44 is applied to the regions where the mask layer 42 and the resin layers 40 and 41 are removed. Thereafter, the mask layer 42 is peeled off. Thereby, the single-layer plates 10 and 30 are formed. It should be noted that a metal may be used as the mask layer 42 instead of the polyethylene terephthalate. Further, the conductive paste 44 may be formed by using the dispensing method or the ink jet method instead of the screen printing.

As illustrated in FIG. 12A, the through hole 25 is formed in the plate member 21. The through hole 25 can be formed using the same method as the through holes 15 and 35 described in FIG. 4A of the first embodiment. Thereafter, the wiring layers 23 and 28 and the through wiring 24 are formed on the plate member 21. The wiring layers 23 and 28 and the through wiring 24 can be formed using the same method as the wiring layers 13 and 33 and the through wirings 14 and 34 described in FIG. 4B of the first embodiment.

As illustrated in FIG. 12B, a mask layer 43 having an opening on the through hole 25 is formed on the upper surface 22a of the plate member 21. The mask layer 43 may be a resist mask or a metal mask, for example.

As illustrated in FIG. 12C, the epoxy resin is applied in the through hole 25 by the screen printing using the mask layer 43 as the mask, so that the resin film 29 is formed in the through hole 25. Thereafter, the mask layer 43 is peeled off. Thereby, the single-layer plate 20 is formed.

As illustrated in FIG. 13A, the single-layer plates 10 and 30 formed according to FIGS. 11A to 11D and the single-layer plate 20 formed according to FIGS. 12A to 12C are stacked. As illustrated in FIG. 13B, the heat pressing, for example, at 200° C., 3 MPa, for 90 minutes is performed to the stacked single-layer plates 10, 20 and 30 by using the vacuum heat press machine. The conductive member 16 made of the conductive paste 44 formed on the plate member 11 is bonded to the through wirings 14 and 24 by the heat pressing. The conductive member 36 made of the conductive paste 44 formed on the plate member 31 is bonded to the through wirings 34 and 14. The resin layers 40 and 41 are cured by the heating, so that the single-layer plates 10, 20 and 30 are bonded and held. The resin films 19, 29, and 39 are cured by the heating and bonded to each other. Thereby, the wiring substrate 300 is formed.

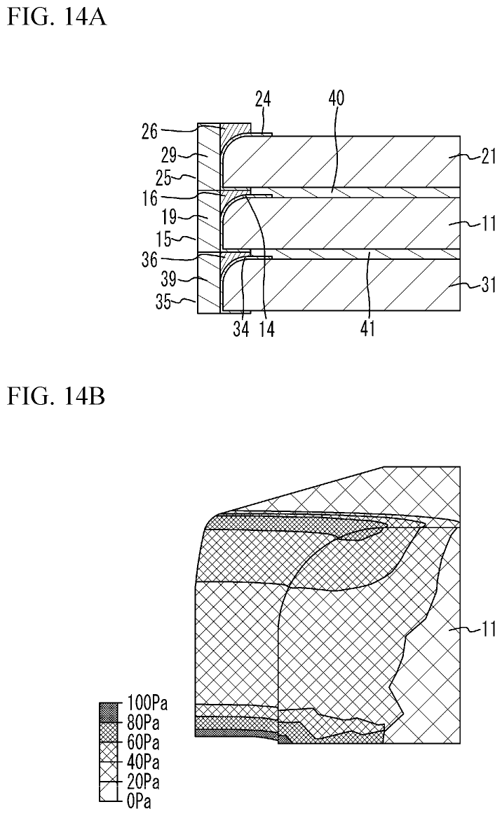

Here, a description will be given of simulation performed on the wiring substrate 300 of the third embodiment. FIG. 14A is a diagram illustrating the structure of the wiring substrate according to the third embodiment in which the simulation has been performed. As illustrated in FIG. 14A, in the wiring substrate of the third embodiment in which the simulation has been performed, the resin films 19, 29, and 39 embedded in the through holes 15, 25, and 35 are made of the epoxy resin. Other configurations are the same as the simulation configuration of FIG. 8A described in the first embodiment. FIG. 14B is a diagram illustrating a simulation result of the wiring substrate according to the third embodiment. As is the case with the simulation of FIGS. 8C and 8D described in the first embodiment, the stress generated in the plate member 11 is calculated in the simulation on the condition that the stacked structure illustrated in FIG. 14A is heat-pressed in the stacking direction at 200° C. and 30 kg/cm². As illustrated in FIG. 14B, in the third embodiment, the stress generated in the plate member 11 is reduced as compared with the comparative example illustrated in FIG. 8D. This is considered to be due to the following reason. That is, in the third embodiment, the resin film 19 having the lower elastic modulus than the conductive member 16 is embedded in the through hole 15. Since the conductive member 61 embedded in the through hole 51 of the plate member 11 in the wiring substrate 500 of the comparative example is made of the same material as the conductive member 16, the resin film 19 has the lower elastic modulus than the conductive member 61. For this reason, it is considered that since the through wiring 14 is easily thermally expanded in the inner direction of the through hole 15 as compared with the comparative example, the stress applied to the plate member 11 is reduced in the third embodiment. Since the through hole 15 has the shape in which the width of the through hole 15 increases from the intermediate portion between the upper surface 12a and the lower surface 12b of the plate member 11 toward the upper surface 12a, it is considered that the portion where the stress tends to concentrate on the plate member 11 is hardly generated. For this reason, it is considered that the stress generated in the plate member 11 is small. Similarly, it is considered that the stress generated in the plate members 21 and 31 is also small.

In the first embodiment, the inner part of the through wiring 14 is hollow, but the resin film 19 having the lower elastic modulus than the conductive member 16 may be embedded in the inner part of the through wiring 14, as described in the third embodiment. Even in this case, the stress generated in the plate member 11 can be reduced as illustrated in FIG. 14B. In order to effectively reduce the stress generated in the plate member 11, the inner part of the through wiring 14 is preferably hollow as in the first embodiment. On the other hand, considering the reliability of the wiring substrate (for example, suppression of oxidation of the through wiring 14) in addition to reducing the stress generated in the plate member 11, the resin film 19 is preferably embedded in the inner part of the through wiring 14.

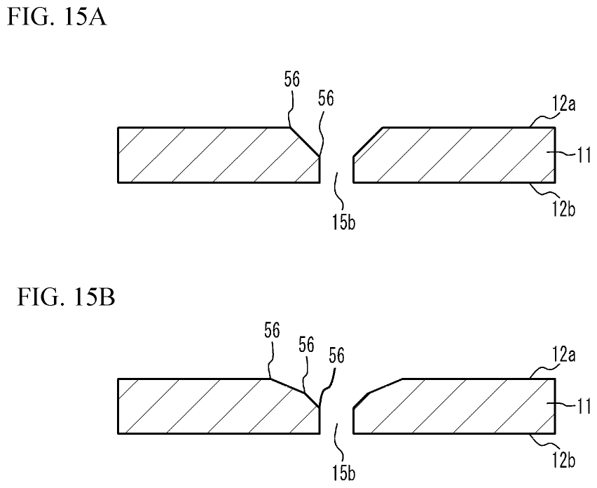

In the first to third embodiments, the description is given of an example in which a portion of the inner peripheral surface of the through hole 15 where the width of the through hole 15 increases from the intermediate portion between the upper surface 12a and the lower surface 12b of the plate member 11 toward the upper surface 12a is inclined in the are shape. However, the above-mentioned portion where the width of the through hole 15 increases may have other shape. FIGS. 15A and 15B are cross-sectional views illustrating other examples of the through hole. As illustrated in FIG. 15A, the portion of the inner peripheral surface of the through hole 15b where the width of the through hole 15b increases from the intermediate portion between the upper surface 12a and the lower surface 12b of the plate member 11 toward the upper surface 12a may be inclined linearly. As illustrated in FIG. 15B, the portion of the inner peripheral surface of the through hole 15b where the width of the through hole 15b increases may be inclined in a polygonal line shape by changing an angle on the way. In these cases, since the angles at the corner portions 56 of the plate member 11 are increased, the stress applied to the corner portions 56 is easily dispersed in the plate member 11, and the stress generated in the plate member 11 can be reduced. Therefore, the occurrence of the cracks in the plate member 11 can be suppressed. It should be noted that the through holes penetrating the plate member 21 and the plate member 31 may have the same shape as the through hole 15b. Further, the portion of the inner peripheral surface of the through hole penetrating the plate member 11 where the width of the through hole increases may be a combination of a linear inclined part and an arcuate inclined part.

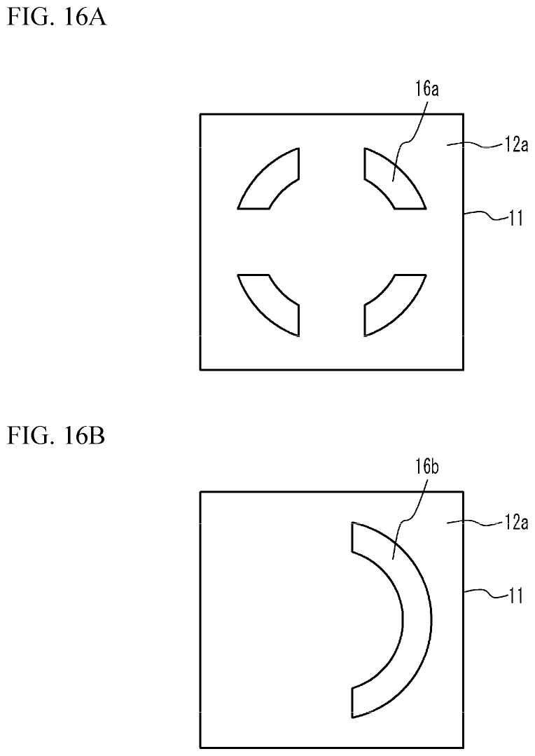

In the first to third embodiments, the description is given of an example in which the conductive member 16 is annularly provided along the end of the through wiring 14. However, the conductive member 16 may have other shape. FIGS. 16A and 16B are plan views illustrating other examples of the conductive member. As illustrated in FIG. 16A, conductive members 16a may be provided in an island shape along the end of the through wiring 14. As illustrated in FIG. 16B, a conductive member 16b may be provided in a semicircular shape along the end of the through wiring 14. In these cases, since the regions where the conductive members 16a and 16b are provided are smaller than the conductive member 16, the stress generated in the plate member 11 due to the thermal expansion of the through wiring 14 is reduced. The conductive member 36 also may have the same shape as the conductive members 16a or 16b. When the conductive member 16a or 16b is provided on the through wiring 14, the through wiring 14 may also be formed in the island shape or the semicircular shape like the conductive member 16a or 16b.

### Fourth Embodiment

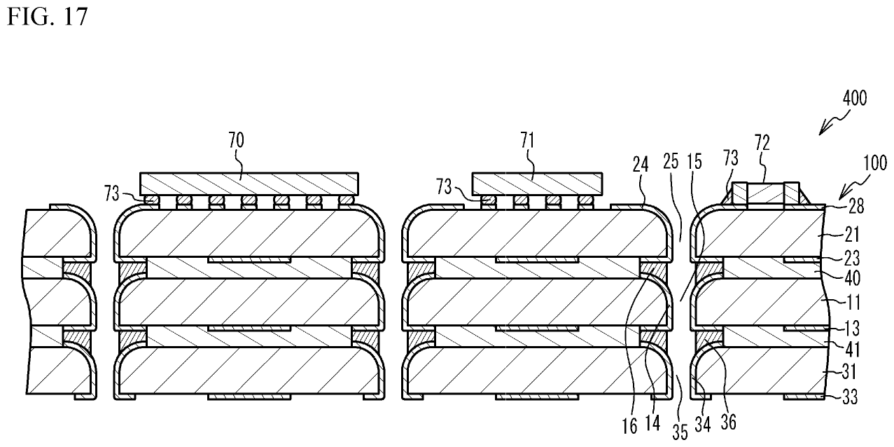

FIG. 17 is a cross-sectional view of an electronic device according to a fourth embodiment. As illustrated in FIG. 17, an electronic device 400 according to the fourth embodiment includes electronic components such as a semiconductor integrated circuit 70, a memory element 71 and/or a capacitor element 72, and the wiring substrate 100 according to the first embodiment. The semiconductor integrated circuit 70 and the memory element 71 are flip-chip mounted, with solder 73, on the wiring layer 28 or the like of the plate member 21 constituting the wiring substrate 100. The capacitor element 72 is mounted on the wiring layer 28 or the like of the plate member 21 with the solder 73.

According to the fourth embodiment, the electronic components such as the semiconductor integrated circuit 70, the memory element 71 and/or the capacitor element 72 are mounted on the wiring substrate 100 in the first embodiment. Thereby, the connection reliability between the through wirings 14, 24, and 34 can be improved, and the occurrence of the cracks in the plate members 11, 21, and 31 can be suppressed. The electronic components such as the semiconductor integrated circuit 70, the memory element 71 and/or the capacitor element 72 may be mounted on the wiring substrate 200 in the second embodiment, or may be mounted on the wiring substrate 300 in the third embodiment.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various change, substitutions, and alterations could be made hereto without departing from the spirit and scope of the invention.

What is claimed is:

1. A wiring substrate comprising:
a first plate member including a first surface and a second surface opposite to the first surface;
a first through wiring configured to extend in a tubular shape from the first surface to the second surface along an inner peripheral surface of a first through hole, the first through hole penetrating the first plate member from the first surface to the second surface and including a shape in which a width of the first through hole increases from an intermediate portion between the first surface and the second surface toward the first surface;
a conductive member provided at an end of the first through wiring on a first surface side of the first plate member;
a second plate member including a third surface and a fourth surface opposite to the third surface, the fourth surface facing the first surface of the first plate member; and
a second through wiring configured to extend from the third surface to the fourth surface along an inner peripheral surface of a second through hole and be in contact with the conductive member, the second through hole penetrating the second plate member from the third surface to the fourth surface.

2. The wiring substrate as claimed in claim 1, wherein
an inner part of the first through wiring is hollow.

3. The wiring substrate as claimed in claim 1, further comprising:
a resin film configured to be embedded in an inner part of the first through wiring and have a lower elastic modulus than the conductive member.

4. The wiring substrate as claimed in claim 1, wherein
a portion of the inner peripheral surface of the first through hole where the width of the first through hole increases from the intermediate portion toward the first surface is inclined in an arc shape.

5. The wiring substrate as claimed in claim 1, wherein
a portion of the inner peripheral surface of the first through hole where the width of the first through hole increases from the intermediate portion toward the first surface is inclined linearly.

6. The wiring substrate as claimed in claim 1, wherein
the second through wiring is provided in a tubular shape on the inner peripheral surface of the second through hole.

7. The wiring substrate as claimed in claim 1, wherein
the conductive member is provided annularly on the first through wiring.

8. The wiring substrate as claimed in claim 1, wherein
the conductive member is provided in an island shape on the first through wiring.

9. The wiring substrate as claimed in claim 1, wherein
the first plate member is made of a brittle material.

10. The wiring substrate as claimed in claim 9, wherein
the brittle material is glass, sapphire, silicon, or gallium nitride.

11. The wiring substrate as claimed in claim 1, wherein
the conductive member is made of a resin containing metal.

12. The wiring substrate as claimed in claim 11, wherein
the metal is an intermetallic compound containing at least one of copper, tin, silver, bismuth, indium, antimony, lead, aluminum, and zinc.

13. The wiring substrate as claimed in claim 1, wherein
the first through wiring is a metal wiring layer including at least one of copper, gold, nickel, aluminum, and palladium.

14. The wiring substrate as claimed in claim 1, wherein
the first through hole has a shape in which the width of the first through hole increases from the intermediate portion toward the first surface and the second surface.

15. The wiring substrate as claimed in claim 1, further comprising:
a resin layer provided between the first surface of the first plate member and the fourth surface of the second plate member.

16. An electronic device comprising:
a wiring substrate; and
an electronic component mounted on the wiring substrate;
the wiring substrate including:
a first plate member including a first surface and a second surface opposite to the first surface;
a first through wiring configured to extend in a tubular shape from the first surface to the second surface along an inner peripheral surface of a first through hole, the first through hole penetrating the first plate member from the first surface to the second surface and including a shape in which a width of the first through hole increases from an intermediate portion between the first surface and the second surface toward the first surface;
a conductive member provided at an end of the first through wiring on a first surface side of the first plate member;
a second plate member including a third surface and a fourth surface opposite to the third surface, the fourth surface facing the first surface of the first plate member; and
a second through wiring configured to extend from the third surface to the fourth surface along an inner peripheral surface of a second through hole and be in contact with the conductive member, the second through hole penetrating the second plate member from the third surface to the fourth surface.
